(19) United States
(12) Patent Application Publication
(10) Pub. No.: US 2022/0293757 A1
(43) Pub. Date: Sep. 15, 2022

(54) NITRIDE SEMICONDUCTOR DEVICE AND METHOD FOR MANUFACTURING SAME

(71) Applicant: ROHM CO., LTD., Kyoto-shi, Kyoto (JP)

(72) Inventor: Hirotaka OTAKE, Kyoto-shi, Kyoto (JP)

(21) Appl. No.: 17/594,987

(22) PCT Filed: Mar. 12, 2020
(86) PCT No.: PCT/JP2020/010866

§ 371 Date: Nov. 4, 2021

(30) Foreign Application Priority Data
May 10, 2019 (JP) 2019-090147

(51) Int. Cl. H01L 29/423; H01L 29/20; H01L 29/778; H01L 29/78; H01L 29/66

(52) U.S. Cl. CPC H01L 29/42364; H01L 29/2003; H01L 29/778; H01L 29/7839; H01L 29/66643; H01L 29/66462

(57) ABSTRACT

A nitride semiconductor device 1 includes a first nitride semiconductor layer 13 that constitutes an electron transit layer, a second nitride semiconductor layer 14 that is formed on the first nitride semiconductor layer and that constitutes an electron supply layer, a semiconductor gate layer 15 that is disposed on the second nitride semiconductor layer and that has a ridge portion 15A at at-least a portion of the semiconductor gate layer and that includes an acceptor type impurity, a gate electrode 4 that is formed at least on the ridge portion of the semiconductor gate layer, a source electrode 3 and a drain electrode 5 that are disposed on the second nitride semiconductor layer, and a hole-pulling-out electrode 6 that is formed on the semiconductor gate layer in order to pull out holes existing in the semiconductor gate layer and that is electrically connected to the source electrode.

### TECHNICAL FIELD

The present invention relates to a nitride semiconductor device that is constituted of a group III nitride semiconductor (hereinafter referred to at times simply as “nitride semiconductor”) and a method for manufacturing the same.

### BACKGROUND ART

A group III nitride semiconductor is a semiconductor among group III-V semiconductors with which nitrogen is used as the group V element. Aluminum nitride (AlN), gallium nitride (GaN), and indium nitride (InN) are representative examples thereof. It can generally be expressed as AlₓIn_{y}Ga_{1-x-y}N (0≤x≤1, 0≤y≤1, 0≤x+y≤1).

An HEMT (high electron mobility transistor) using such a nitride semiconductor has been proposed. Such an HEMT includes, for example, an electron transit layer constituted of GaN and an electron supply layer constituted of an AlGaN epitaxially grown on the electron transit layer. A pair of source electrode and drain electrode are formed such as to contact the electron supply layer and a gate electrode is disposed therebetween.

Due to polarization caused by lattice mismatch of GaN and the AlGaN, a two-dimensional electron gas is formed at a position inside the electron transit layer that is only a few Å inward from an interface between the electron transit layer and the electron supply layer. A source and a drain are connected to each other with the two-dimensional electron gas as a channel. When the two-dimensional electron gas is interrupted by application of a control voltage to the gate electrode, the source and the drain are interrupted from each other. The source and the drain are made conductive to each other in a state where the control voltage is not applied to the gate electrode and therefore the device is of a normally-on type.

Devices using a nitride semiconductor have features, such as high withstand voltage, high temperature operation, high current density, high speed switching, and low on resistance, and therefore application to power devices have been proposed in, for example, Patent Literature 1, and devices having such a concept are mass-produced nowadays, and are distributed to the market.

Patent Literature 1 discloses an arrangement in which a p type GaN gate layer (semiconductor gate layer) having a ridge shape is laminated on an AlGaN electron supply layer, and a gate electrode is disposed thereon, and a channel is eliminated by a depletion layer spreading from the p type GaN gate layer to achieve a normally-off operation.

However, in a normally-off type nitride semiconductor HEMT using the p type GaN gate layer, a valence band groove in which holes are accumulated is formed near an interface with the AlGaN electron supply layer in the p type GaN gate layer. Therefore, in the nitride semiconductor HEMT described in Patent Literature 1, there is a concern that holes cannot be easily released, and fluctuation of a gate threshold may occur if the holes are injected into the p type GaN gate layer. This tendency has a larger influence when a Schottky junction is formed between the gate electrode and the pGaN gate layer.

To solve this problem, Patent Literature 2 proposes to form a laminated film constituted of an AlN layer and an AlGaN layer between a p type GaN gate layer and a source electrode on an AlGaN electron supply layer and to generate a two-dimensional hole gas near an interface between the AlN layer and the AlGaN layer, thereby pulling out the holes existing in the p type GaN gate layer toward the source electrode side.

### CITATION LIST

### Patent Literature

Patent Literature 1: Japanese Patent Application Publication No. 2017-73506

### SUMMARY OF INVENTION

### Technical Problem

However, disadvantageously, in the nitride semiconductor HEMT described in Patent Literature 2, the AlN layer and the AlGaN layer are required to be grown on the AlGaN electron supply layer after forming the p type GaN gate layer having the ridge shape on the AlGaN electron supply layer, and it is difficult to secure crystal quality. Additionally, a regrowth step is needed, and therefore the antinomy of an increase in cost exists.

An object of the present invention is to provide a nitride semiconductor device capable of pulling out holes existing in a semiconductor gate layer toward the source electrode side without growing a crystal on an electron supply layer after forming the semiconductor gate layer, and to provide a method for manufacturing the nitride semiconductor device.

### Solution to Problem

One preferred embodiment of the present invention provides a nitride semiconductor device including a first nitride semiconductor layer that constitutes an electron transit layer, a second nitride semiconductor layer that is formed on the first nitride semiconductor layer and that constitutes an electron supply layer, a semiconductor gate layer that is disposed on the second nitride semiconductor layer and that has a ridge portion at at-least a portion of the semiconductor gate layer and that includes an acceptor type impurity, a gate electrode that is formed at least on the ridge portion of the semiconductor gate layer, a source electrode and a drain electrode that are disposed on the second nitride semiconductor layer, and a hole-pulling-out electrode that is formed on the semiconductor gate layer in order to pull out holes existing in the semiconductor gate layer and that is electrically connected to the source electrode.

With this arrangement, it is possible to pull out holes existing in the semiconductor gate layer toward the source electrode side without growing a crystal on the electron supply layer after forming the semiconductor gate layer.

In one preferred embodiment of the present invention, the source electrode has a source principal electrode portion parallel to the ridge portion, the drain electrode is disposed so as to face the source principal electrode portion across the ridge portion, the semiconductor gate layer has an extension portion formed in a region in which the source principal electrode portion and the drain electrode do not face each other, and the hole-pulling-out electrode is formed in a region in which the gate electrode is not formed in a front surface of the extension portion.

In one preferred embodiment of the present invention, the semiconductor gate layer is disposed so as to surround the source principal electrode portion in a plan view, the semiconductor gate layer has a pair of the ridge portions respectively disposed at both sides of the source principal electrode portion and two ridge coupling portions that couple corresponding end portions of these ridge portions together, the drain electrode faces the source principal electrode portion across one of the pair of the ridge portions, and the hole-pulling-out electrode is formed on at least one of the two ridge coupling portions.

In one preferred embodiment of the present invention, the gate electrode has a pair of gate principal electrode portions formed on the pair of the ridge portions, respectively, and two base portions that are formed on the ridge coupling portion and that couple corresponding end portions of the pair of the gate principal electrode portions together, a removed region in which the base portion is not formed is formed at at-least one of the two base portions, and the hole-pulling-out electrode is formed on a front surface of the ridge coupling portion in the removed region.

In one preferred embodiment of the present invention, the gate principal electrode portion and the drain electrode are disposed at both sides of the source principal electrode portion in order of short-to-long distance from the source principal electrode portion.

In one preferred embodiment of the present invention, a thickness of a region in which the hole-pulling-out electrode is formed in the semiconductor gate layer is thinner than a thickness of the ridge portion.

In one preferred embodiment of the present invention, the ridge coupling portion directly under the removed region has a thin film region whose thickness is thinner than a thickness of the ridge portion, and the hole-pulling-out electrode is formed on a front surface of the thin film region.

In one preferred embodiment of the present invention, the hole-pulling-out electrode and the gate electrode are constituted of mutually different materials.

In one preferred embodiment of the present invention, the gate electrode makes a first Schottky contact with the semiconductor gate layer, the hole-pulling-out electrode makes a second Schottky contact with the semiconductor gate layer, and the first Schottky contact is higher in barrier height against holes than the second Schottky contact.

In one preferred embodiment of the present invention, the gate electrode makes a Schottky contact with the semiconductor gate layer, and the hole-pulling-out electrode makes an ohmic contact with the semiconductor gate layer.

In one preferred embodiment of the present invention, a third nitride semiconductor layer is formed between the hole-pulling-out electrode and the semiconductor gate layer.

In one preferred embodiment of the present invention, the first nitride semiconductor layer is constituted of a GaN layer, the second nitride semiconductor layer is constituted of an AlₓGa₍₁₋ₓ₎N (0<x<1) layer, and the semiconductor gate layer is constituted of a p type GaN layer.

One preferred embodiment of the present invention provides a method for manufacturing a nitride semiconductor device, and the method includes a step of forming a first nitride semiconductor layer that constitutes an electron transit layer, a second nitride semiconductor layer that constitutes an electron supply layer, and a semiconductor gate layer material film that includes an acceptor type impurity in this order on a substrate, a step of forming an electrode film that is a material film for a gate electrode and a hole-pulling-out electrode on the semiconductor gate layer material film, a step of forming a semiconductor gate layer having a ridge portion that has a ridge shape and an extension portion that extends from the ridge portion and an electrode film formed on the semiconductor gate layer by means of patterning achieved by etching the electrode film and the semiconductor gate layer material film, a step of forming a first dielectric film so as to cover exposed surfaces of the electrode film, of the semiconductor gate layer, and of the second nitride semiconductor layer, and hereafter forming a source contact hole and a drain contact hole that penetrate through the first dielectric film in a thickness direction at mutually-facing positions between which the ridge portion is interposed in the first dielectric film, a step of forming a source electrode and a drain electrode that penetrate through the source contact hole and the drain contact hole and that come into contact with the second nitride semiconductor layer, and a step of, in the extension portion, forming a first annular opening portion having an annular shape in a plan view in the first dielectric film and forming a second annular opening portion having an annular shape in a plan view that communicates with the first annular opening portion in the electrode film, and hence forming the hole-pulling-out electrode that is constituted of the electrode film disposed inside the second annular opening portion and that comes into contact with the extension portion and the gate electrode that is constituted of the electrode film disposed outside the second annular opening portion. The term “annular shape” includes closed-curve shape, such as elliptical annular shape, quadrangular annular shape, or triangular annular shape, in addition to circular annular shape.

In this manufacturing method, it is possible to manufacture a nitride semiconductor device capable of pulling out holes existing in the semiconductor gate layer toward the source electrode side without growing a crystal on the electron supply layer after forming the semiconductor gate layer.

One preferred embodiment of the present invention provides a method for manufacturing a nitride semiconductor device, and the method includes a step of forming a first nitride semiconductor layer that constitutes an electron transit layer, a second nitride semiconductor layer that constitutes an electron supply layer, and a semiconductor gate layer material film that includes an acceptor type impurity in this order on a substrate, a step of forming a gate electrode film that is a material film for a gate electrode on the semiconductor gate layer material film, a step of forming a semiconductor gate layer having a ridge portion that has a ridge shape and an extension portion that extends from the ridge portion and a gate electrode film formed on the semiconductor gate layer by means of patterning achieved by etching the gate electrode film and the semiconductor gate layer material film, a step of forming a first dielectric film so as to cover exposed surfaces of the gate electrode film, of the semiconductor gate layer, and of the second nitride semiconductor layer, and hereafter forming a source contact hole and a drain contact hole that penetrate through the first dielectric film in a thickness direction at mutually-facing positions between which the ridge portion is interposed in the first dielectric film, a step of forming a source electrode and a drain electrode that penetrate through the source contact hole and the drain contact hole and that come into contact with the second nitride semiconductor layer, a step of, in the extension portion, forming a first opening portion that penetrates through the first dielectric film in a thickness direction and forming a second opening portion that communicates with the first opening portion in the gate electrode film, and hence forming a gate electrode, a step of forming a second dielectric film with which a bottom surface of the second opening portion is covered, a step of forming a third opening portion that penetrates through the second dielectric film in the thickness direction in the second dielectric film, and a hole-pulling-out electrode forming step of forming a hole-pulling-out electrode that covers the third opening portion and that comes into contact with the extension portion.

In this manufacturing method, it is possible to manufacture a nitride semiconductor device capable of pulling out holes existing in the semiconductor gate layer toward the source electrode side without growing a crystal on the electron supply layer after forming the semiconductor gate layer.

In one preferred embodiment of the present invention, the hole-pulling-out electrode forming step includes a step of forming a concave portion that communicates with the third opening portion at a front surface of the extension portion and a step of forming a hole-pulling-out electrode that is formed on the second dielectric film so as to cover the third opening portion and that has a portion in contact with the extension portion in the concave portion.

The aforementioned as well as yet other objects, features, and effects of the present invention will be made clear by the following description of the preferred embodiments made with reference to the accompanying drawings.

### BRIEF DESCRIPTION OF DRAWINGS

FIG. 1 is a partial plan view for describing the arrangement of a nitride semiconductor device according to a first preferred embodiment of the present invention.

FIG. 2 is an enlarged sectional view taken along line II-II of FIG. 1.

FIG. 3 is an enlarged sectional view taken along line III-III of FIG. 1.

FIG. 4A is a sectional view of an example of a manufacturing process of the nitride semiconductor device of FIG. 1 and is a sectional view corresponding to the section plane of FIG. 2.

FIG. 4B is a sectional view showing a step subsequent to that of FIG. 4A.

FIG. 4C is a sectional view showing a step subsequent to that of FIG. 4B.

FIG. 4D is a sectional view showing a step subsequent to that of FIG. 4C.

FIG. 4E is a sectional view showing a step subsequent to that of FIG. 4D.

FIG. 5A is a sectional view of the example of the manufacturing process of the nitride semiconductor device of FIG. 1 and is a sectional view corresponding to the section plane of FIG. 3.

FIG. 5B is a sectional view showing a step subsequent to that of FIG. 5A.

FIG. 5C is a sectional view showing a step subsequent to that of FIG. 5B.

FIG. 5D is a sectional view showing a step subsequent to that of FIG. 5C.

FIG. 5E is a sectional view showing a step subsequent to that of FIG. 5D.

FIG. 5F is a sectional view showing a step subsequent to that of FIG. 5E.

FIG. 6 is a graph showing a result of an I_{G}−V_{GS} measurement experiment performed with respect to a comparative example.

FIG. 7 is a graph showing a measurement result of a drain current I_{D} with respect to a gate-source voltage V_{GS} performed with respect to the comparative example.

FIG. 8 is an energy distribution view for describing a reason why a threshold voltage decreases in the comparative example.

FIG. 9 is a circuit diagram showing an equivalent circuit corresponding to a gate-source structure of the nitride semiconductor device of FIG. 1.

FIG. 10 is a plan view for describing an arrangement of a nitride semiconductor device according to a second preferred embodiment of the present invention.

FIG. 11 is a sectional view along line XI-XI of FIG. 10.

FIG. 12 is a sectional view along line XII-XII of FIG. 10.

FIG. 13A is a sectional view showing an example of a manufacturing process of the nitride semiconductor device of FIG. 10, and is a sectional view corresponding to a section plane of FIG. 11.

FIG. 13B is a sectional view showing a step subsequent to that of FIG. 13A.

FIG. 14A is a sectional view showing an example of a manufacturing process of the nitride semiconductor device of FIG. 10, and is a sectional view corresponding to a section plane of FIG. 12.

FIG. 14B is a sectional view showing a step subsequent to that of FIG. 14A.

FIG. 14C is a sectional view showing a step subsequent to that of FIG. 14B.

FIG. 15 is a plan view for describing a nitride semiconductor device according to a third preferred embodiment of the present invention.

FIG. 16 is a sectional view along line A-B-C of FIG. 15.

FIG. 17 is a sectional view showing a first modification example of the nitride semiconductor device according to the third preferred embodiment.

FIG. 18 is a sectional view showing a second modification example of the nitride semiconductor device according to the third preferred embodiment.

FIG. 19 is a sectional view showing a third modification example of the nitride semiconductor device according to the third preferred embodiment.

### DESCRIPTION OF EMBODIMENTS

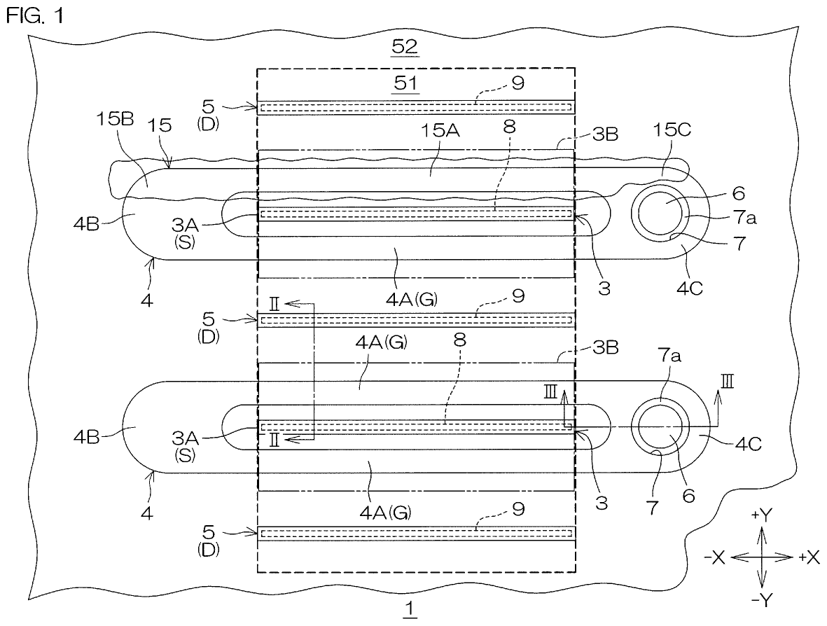

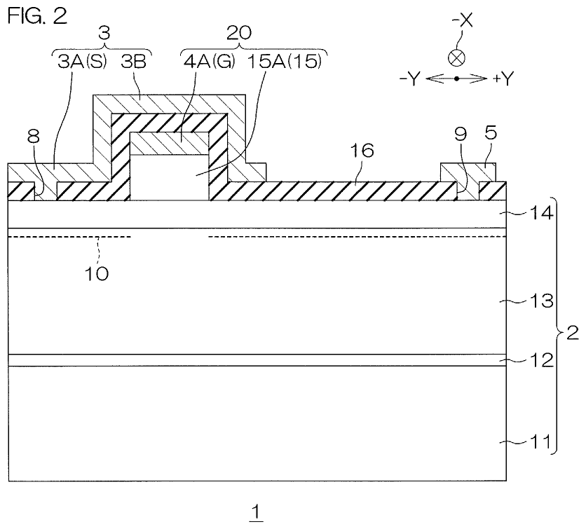

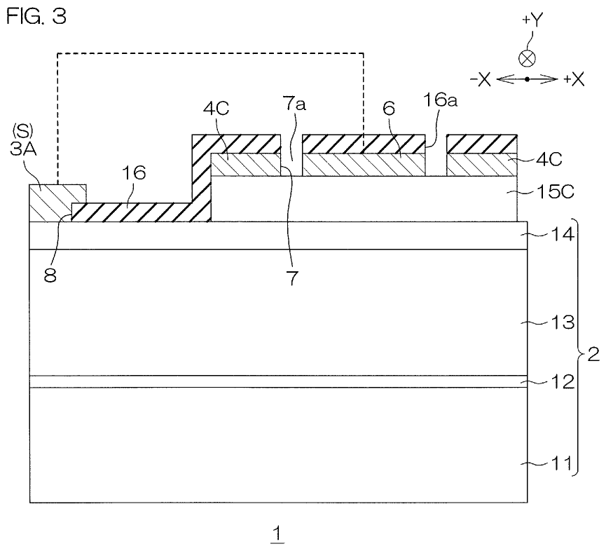

FIG. 1 is a partial plan view for describing the arrangement of a nitride semiconductor device according to a first preferred embodiment of the present invention. FIG. 2 is an enlarged sectional view taken along line II-II of FIG. 1. FIG. 3 is an enlarged sectional view taken along line III-III of FIG. 1.

For descriptive convenience, a passivation film represented by reference sign 16 in FIG. 2 and FIG. 3 is omitted in FIG. 1. Additionally, for descriptive convenience, a source principal electrode portion 3A represented by reference sign 3A in FIG. 2 is shown by a solid line, and an extension portion 3B represented by reference sign 3B in FIG. 2 is omitted in FIG. 1. However, the outline of the extension portion 3B is shown by an alternate long and two short dashed line in FIG. 1.

Additionally, for convenience of description, a +X direction, a −X direction, a +Y direction, and a −Y direction shown in FIG. 1, FIG. 2, and FIG. 3 are used at times in the following description. The +X direction is a predetermined direction along a front surface of the nitride semiconductor device 1 in plan view and the +Y direction is a direction along the front surface of the nitride semiconductor device 1 and is a direction that is orthogonal to the +X direction. The −X direction is a direction opposite to the +X direction and the −Y direction is a direction opposite to the +Y direction. The +X direction and the −X direction shall be referred to simply as the “X direction” when referred to collectively, and the +Y direction and the −Y direction shall be referred to simply as the “Y direction” when referred to collectively.

The nitride semiconductor device 1 includes a semiconductor laminated structure (nitride semiconductor structure) 2 and an electrode metal structure disposed on the semiconductor laminated structure 2.

As shown in FIG. 1, the electrode metal structure includes a plurality of source electrodes 3, a plurality of gate electrodes 4, a plurality of drain electrodes 5, and a plurality of hole-pulling-out electrodes 6. The source electrodes 3 and the drain electrodes 5 extend in the X direction. Each of the gate electrodes 4 includes a pair of gate principal electrode portions 4A that extend in parallel with each other in the X direction and two base portions 4B and 4C that respectively couple corresponding end portions of the pair of gate principal electrode portions 4A together. In the following description, one of the two base portions 4B and 4C will be referred to at times as the “first base portion 4B,” and the other one will be referred to at times as the “second base portion 4C.”

A removed region 7 that is circular in a plan view is formed at the second base portion 4C. The removed region 7 is a region in which the gate electrode 4 is not formed. The hole-pulling-out electrode 6 is disposed in the removed region 7. An interval is provided between the gate electrode 4 and the hole-pulling-out electrode 6, and these electrodes are insulated from each other.

The single source electrode 3 is formed so as to cover substantially the entire region of the pair of gate principal electrode portions 4A of the single gate electrode 4 in a plan view. The source electrode 3 is constituted of a source principal electrode portion 3A disposed at a width central portion between the pair of gate principal electrode portions 4A and the extension portion 3B around the source principal electrode portion 3A in a plan view. In this preferred embodiment, the source principal electrode portion 3A shall refer to a region constituted of a region surrounded by the outline of a source contact hole 8 and a region therearound of the entire region of the source electrode 3 in a plan view. The extension portion 3B refers to a portion of the entire region of the source electrode 3 other than the source principal electrode portion 3A in a plan view. The extension portion 3B covers substantially the entire region of the pair of gate principal electrode portions 4A.

The drain electrodes 5 are respectively disposed at both sides of the single source electrode 3. The drain electrode 5 and the source principal electrode portion 3A that are mutually adjacent face each other across the gate principal electrode portion 4A. In this preferred embodiment, the length of the drain electrode 5 and the length of the source principal electrode portion 3A are substantially equal to each other, and the position in the X direction of each of both ends of the drain electrode 5 and the position in the X direction of a corresponding end of the source principal electrode portion 3A substantially coincide with each other.

In the example of FIG. 1, the source principal electrode portions 3A (S), the gate principal electrode portions 4A (G), and the drain electrode 5A (D) are disposed cyclically in an order of DGSGDGS in the Y direction. Thereby, element structures are arranged by each gate principal electrode portion 4A (G) being sandwiched by a source principal electrode portion 3A (S) and a drain electrode (D). A region of a front surface on the semiconductor laminated structure 2 is constituted of an active area 51 that includes the element structures and a nonactive area 52 at an outer side of the active area 51. The base portions 4B of each gate electrode 4 respectively couple the corresponding end portions of the plurality of gate principal electrode portions 4A to each other in the nonactive area 52.

As shown in FIG. 2 and FIG. 3, the semiconductor laminated structure 2 includes a substrate 11, a buffer layer 12 that is formed on a front surface of the substrate 11, a first nitride semiconductor layer 13 that is epitaxially grown on the buffer layer 12, and a second nitride semiconductor layer 14 that is epitaxially grown on the first nitride semiconductor layer 13.

The substrate 11 may, for example, be a silicon substrate of low resistance. The silicon substrate of low resistance may be a p type substrate having an electric resistivity of, for example, 0.001 Ωmm to 0.5 Ωmm (more specifically, approximately 0.01 Ωmm to 0.1 Ωmm). Also, besides a silicon substrate of low resistance, the substrate 11 may instead be an SiC substrate of low resistance, a GaN substrate of low resistance, etc. The substrate 11 has a thickness, for example, of approximately 650 μm during a semiconductor process and is ground to not more than approximately 300 μm in a preliminary stage before being made into a chip. The substrate 11 is electrically connected to the source electrode 3.

In this preferred embodiment, the buffer layer 12 is constituted of a multilayer buffer layer in which a plurality of nitride semiconductor films are laminated. In this preferred embodiment, the buffer layer 12 is constituted of a first buffer layer (not shown) constituted of an AlN film in contact with the front surface of the substrate 11 and a second buffer layer (not shown) constituted of an AlN/AlGaN superlattice layer laminated on a front surface of the first buffer layer (the front surface at an opposite side to the substrate 11 side). A film thickness of the first buffer layer is approximately 100 nm to 500 nm. A film thickness of the second buffer layer is approximately 500 nm to 2 μm. The buffer layer 12 may instead be constituted, for example, of a single film or a composite film of AlGaN.

The first nitride semiconductor layer 13 constitutes an electron transit layer. In this preferred embodiment, the first nitride semiconductor layer 13 is constituted of a GaN layer and a thickness thereof is approximately 0.5 μm to 2 μm. Also, an impurity for making a region other than a front surface region semi-insulating may be introduced for a purpose of suppressing a leak current that flows through the first nitride semiconductor layer 13. In this case, a concentration of the impurity is preferably not less than 4×10¹⁶ cm⁻³. Also, the impurity is, for example, C or Fe.

The second nitride semiconductor layer 14 constitutes an electron supply layer. The second nitride semiconductor layer 14 is constituted of a nitride semiconductor with a larger bandgap than the first nitride semiconductor layer 13. In this preferred embodiment, the second nitride semiconductor layer 14 is constituted of a nitride semiconductor with a higher Al composition than the first nitride semiconductor layer 13. In a nitride semiconductor, the higher the Al composition, the larger the bandgap. In this preferred embodiment, the second nitride semiconductor layer 14 is constituted of an Alₓ₁Ga₁₋ₓ₁N layer (0<x1<1) and a thickness thereof is approximately 5 nm to 25 nm.

The first nitride semiconductor layer (electron transit layer) 13 and the second nitride semiconductor layer (electron supply layer) 14 are thus constituted of nitride semiconductors that differ in bandgap (Al composition) and a lattice mismatch occurs therebetween. Also, due to spontaneous polarizations of the first nitride semiconductor layer 13 and the second nitride semiconductor layer 14 and a piezo polarization due to the lattice mismatch between the two, an energy level of a conduction band of the first nitride semiconductor layer 13 at an interface between the first nitride semiconductor layer 13 and the second nitride semiconductor layer 14 is made lower than a Fermi level. Thereby, inside the first nitride semiconductor layer 13, a two-dimensional electron gas (2DEG) 10 spreads at a position close to the interface between the first nitride semiconductor layer 13 and the second nitride semiconductor layer 14 (for example, at a distance of approximately several Å from the interface).

A semiconductor gate layer 15 is interposed between the second nitride semiconductor layer 14 and the gate electrode 4 (4A, 4B, 4C). The semiconductor gate layer 15 is formed on the front surface of the second nitride semiconductor layer 14 by epitaxial growth. The semiconductor gate layer 15 has substantially the same shape as the gate electrode 4 in a plan view. Specifically, the semiconductor gate layer 15 includes a pair of ridge portions 15A that extend in the X direction in parallel with each other and two ridge coupling portions 15B and 15C that respectively couple corresponding end portions of the pair of ridge portions 15A together. In the following description, one of the two ridge coupling portions 15B and 15C will be referred to at times as the “first ridge coupling portion 15B,” and the other one will be referred to at times as the “second ridge coupling portion 15C.” The second ridge coupling portion 15C is an example of the “extension portion” of the present invention.

As shown in FIG. 1, FIG. 2, and FIG. 3, the gate principal electrode portion 4A of the gate electrode 4 is formed on the ridge portion 15A of the semiconductor gate layer 15, and the first and second base portions 4B and 4C of the gate electrode 4 are formed on the first and second ridge coupling portions 15B and 15C of the semiconductor gate layer 15, respectively. Therefore, as shown in FIG. 1, the semiconductor gate layer 15 is formed so as to surround the source principal electrode portion 3A in the same way as the gate electrode 4 in a plan view. That is, the gate electrode 4 and the semiconductor gate layer 15 are each formed in an annular shape in a plan view. As shown in FIG. 2, a gate portion 20 is formed by the ridge portion 15A of the semiconductor gate layer 15 and the gate principal electrode portion 4A of the gate electrode 4 formed on the ridge portion 15A.

The semiconductor gate layer 15 is constituted of a nitride semiconductor doped with an acceptor type impurity. In this preferred embodiment, the semiconductor gate layer 15 is constituted of a GaN layer (p type GaN layer) doped with an acceptor type impurity. The thickness of the semiconductor gate layer 15 is preferably 40 nm to 150 nm, and more preferably 40 nm to 100 nm. Preferably, the concentration of the acceptor type impurity injected into the semiconductor gate layer 15 is 1×10¹⁹ cm⁻³ or more. In this preferred embodiment, the acceptor type impurity is Mg (magnesium). The acceptor type impurity may be an acceptor type impurity, such as Zn (zinc), other than Mg. The semiconductor gate layer 15 (15A) is provided in order to eliminate a two-dimensional electron gas 10 generated near the interface between the first nitride semiconductor layer (electron transit layer) 13 and the second nitride semiconductor layer (electron supply layer) 14 in a region directly under the gate portion 20 in a stationary state without the application of a voltage.

In this preferred embodiment, the gate electrode 4 is constituted of TiN. The film thickness of the gate electrode 4 is approximately 50 nm to 200 nm.

The removed region 7 having a circular shape in a plan view is formed at the second base portion 4C of the gate electrode 4 as shown in FIG. 1 and FIG. 3. The hole-pulling-out electrode 6 serving to pull out holes in the semiconductor gate layer 15 is formed on a front surface exposed to the removed region 7 in the second ridge coupling portion 15C of the semiconductor gate layer 15. An annular space portion 7a having an annular shape in a plan view is formed between the hole-pulling-out electrode 6 and the second base portion 4C of the gate electrode 4 in a plan view. In this preferred embodiment, the hole-pulling-out electrode 6 is constituted of TiN. The film thickness of the hole-pulling-out electrode 6 is approximately 50 nm to 200 nm.

As shown in FIG. 2 and FIG. 3, a passivation film (first dielectric film) 16 that covers exposed surfaces of the gate electrode 4, of the hole-pulling-out electrode 6, and of the semiconductor gate layer 15 (excluding a region facing the annular space portion 7a) and an exposed surface of the second nitride semiconductor layer 14 (excluding regions facing the source and drain contact holes 8 and 9) is formed on the second nitride semiconductor layer 14.

In this preferred embodiment, the passivation film 16 is constituted of an SiN film, and its thickness is approximately 50 nm to 200 nm. The passivation film 16 may be constituted of a single film of any one among SiN, SiO₂, and SiON, or may be constituted of a composite film of an arbitrary combination thereamong.

An annular opening portion 16a, which has an annular shape in a plan view and which penetrates through the passivation film 16 in the thickness direction and which communicates with the annular space portion 7a, and a contact hole 8 and a drain contact hole 9 both of which penetrate through the passivation film 16 in the thickness direction are formed in the passivation film 16. The source contact hole 8 and the drain contact hole 9 are formed so as to sandwich the gate portion 20 therebetween.

The source principal electrode portion 3A of the source electrode 3 penetrates through the source contact hole 8, and comes into contact with the second nitride semiconductor layer 14. As shown in FIG. 1 and FIG. 2, the extension portion 3B of the source electrode 3 covers the gate portion 20 (gate principal electrode portion 4A) in the active area 51. The drain electrode 5 penetrates through the drain contact hole 9, and comes into contact with the second nitride semiconductor layer 14. The source electrode 3 and the drain electrode 5 make an ohmic contact with the two-dimensional electron gas 10.

The source electrode 3 and the drain electrode 5 are each constituted of, for example, a first metal layer (ohmic metal layer) in contact with the second nitride semiconductor layer 14, a second metal layer (principal electrode metal layer) laminated on the first metal layer, a third metal layer (adhesion layer) laminated on the second metal layer, and a fourth metal layer (barrier metal layer) laminated on the third metal layer. The first metal layer is, for example, a Ti layer whose thickness is approximately 10 nm to 20 nm. The second metal layer is, for example, a layer including Al whose thickness is approximately 100 nm to 300 nm. The third metal layer is, for example, a Ti layer whose thickness is approximately 10 nm to 20 nm. The fourth metal layer is, for example, a TiN layer whose thickness is approximately 10 nm to 50 nm.

The hole-pulling-out electrode 6 is electrically connected to the source electrode 3 through an internal electric wiring (a via plug, a wiring film, etc.) not shown.

In the nitride semiconductor device 1, a heterojunction is formed by there being formed on the first nitride semiconductor layer (electron transit layer) 13, the second nitride semiconductor layer (electron supply layer) 14 that differs in bandgap (Al composition). The two-dimensional electron gas 10 is thereby formed inside the first nitride semiconductor layer 13 near the interface between the first nitride semiconductor layer 13 and the second nitride semiconductor layer 14, and an HEMT making use of the two-dimensional electron gas 10 as a channel is formed. The gate principal electrode portions 4A of the gate electrodes 4 oppose the second nitride semiconductor layer 14 across the ridge portions 15A of the semiconductor gate layers 15.

Below the gate principal electrode portions 4A, energy levels of the first nitride semiconductor layer 13 and the second nitride semiconductor layer 14 are pulled up by the ionized acceptors contained in the ridge portions 15A that are constituted of the p type GaN layers. The energy level of the conduction band at the heterojunction interface between the first nitride semiconductor layer 13 and the second nitride semiconductor layer 14 is thus made higher than the Fermi level. Therefore, the two-dimensional electron gas 10 due to the spontaneous polarizations of the first nitride semiconductor layer 13 and the second nitride semiconductor layer 14 and the piezo polarization due to the lattice mismatch of the two layers is not formed directly below the gate principal electrode portions 4A (gate portions 20).

Therefore, when a bias is not applied to the gate electrodes 4 (zero bias state), the channel due to the two-dimensional electron gas 10 is interrupted directly below the gate principal electrode portions 4A. A normally-off type HEMT is thus realized. When an appropriate on voltage (for example, of 5 V) is applied to the gate electrodes 4, channels are induced inside the first nitride semiconductor layer 13 directly below the gate principal electrode portions 4A and the two-dimensional electron gas 10 at both sides of each gate principal electrode portion 4A becomes connected. A source and a drain are thereby made continuous to each other.

For use, for example, a predetermined voltage (for example, of 10 V to 500 V) with which the drain electrode 5 side becomes positive is applied between the source electrodes 3 and the drain electrodes 5. In this state, an off voltage (0 V) or the on voltage (5 V) is applied to the gate electrodes 4 with the source electrodes 3 being at a reference potential (0 V).

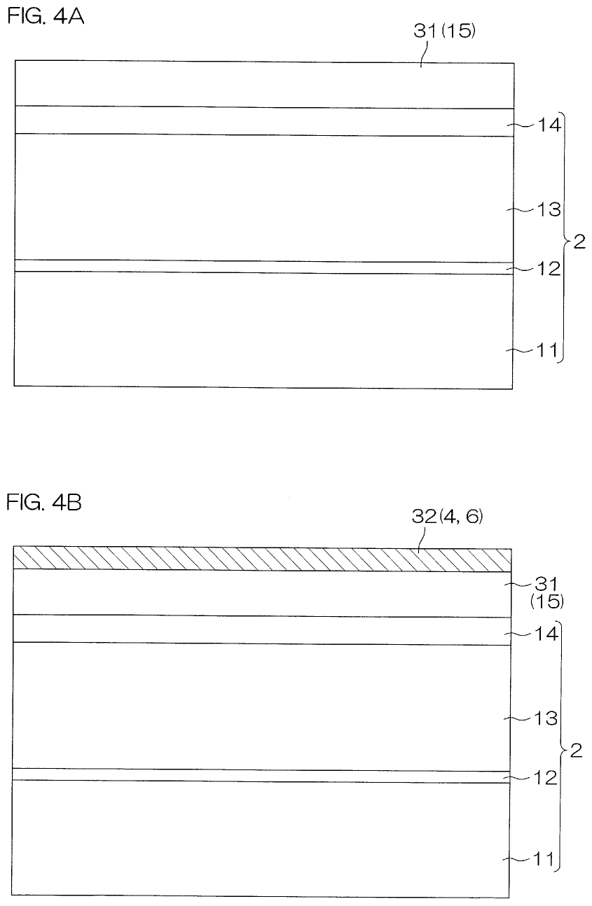

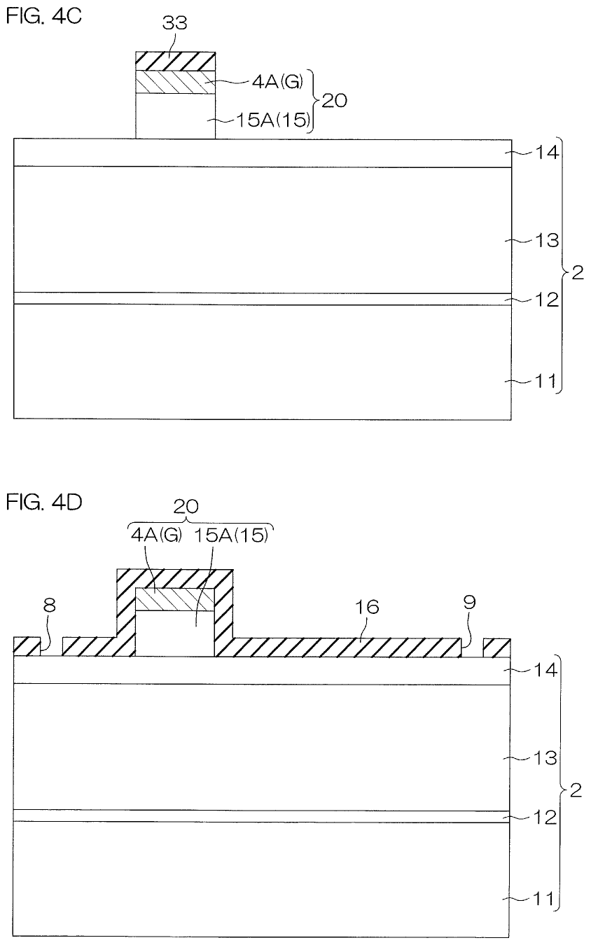

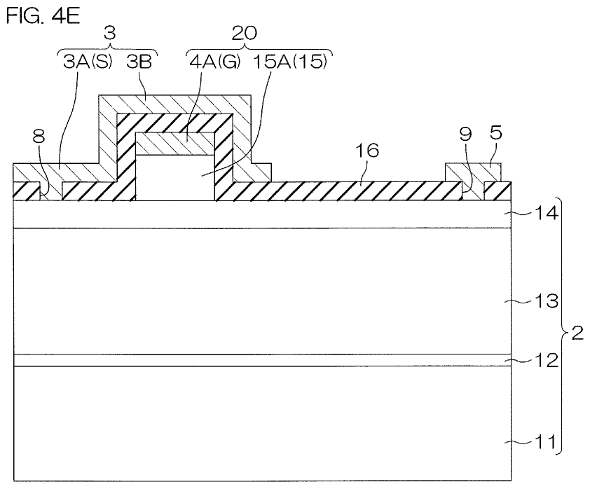

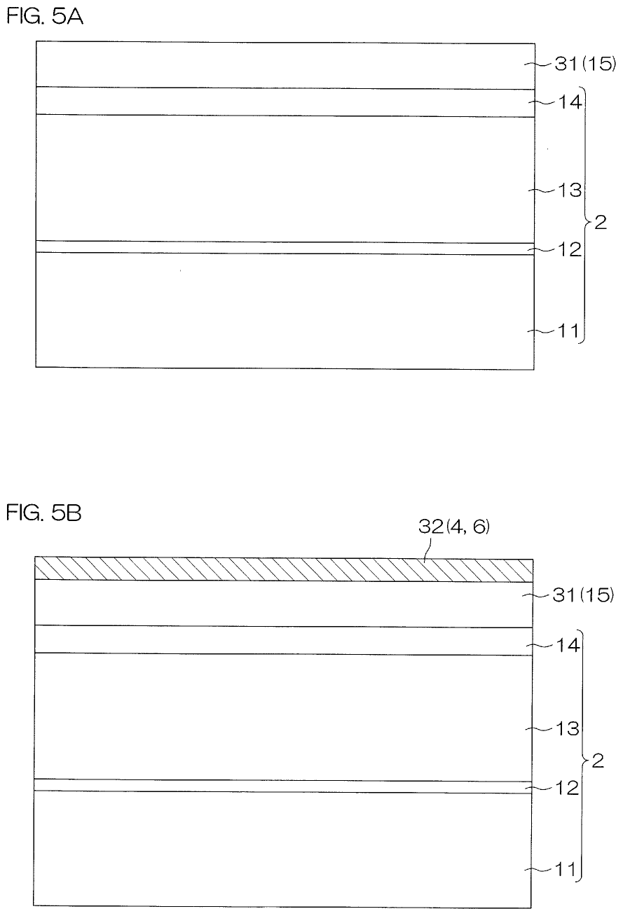

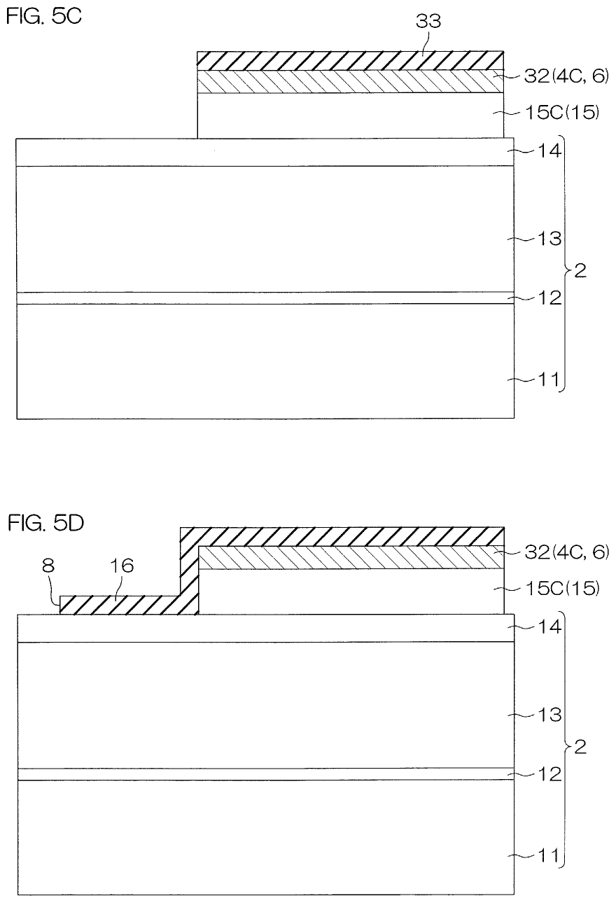

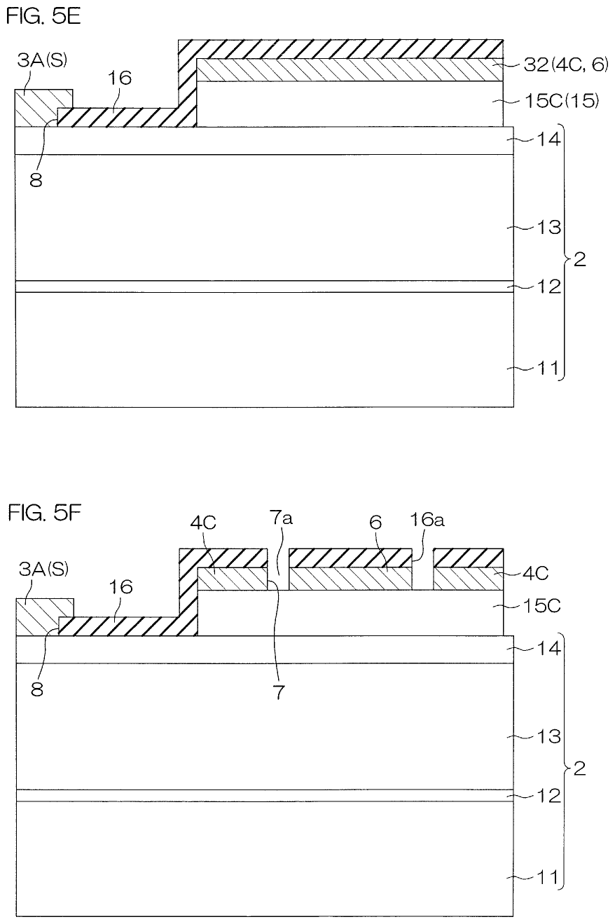

FIG. 4A to FIG. 4E and FIG. 5A to FIG. 5F are sectional views for describing an example of a manufacturing process of the nitride semiconductor device 1, in which a cross-sectional structure in a plurality of steps of the manufacturing process is shown. FIG. 4A to FIG. 4E are sectional views corresponding to the section plane of FIG. 2, and FIG. 5A to FIG. 5F are sectional views corresponding to the section plane of FIG. 3.

First, as shown in FIG. 4A and FIG. 5A, the buffer layer 12, the first nitride semiconductor layer 13, and the second nitride semiconductor layer 14 are epitaxially grown on the substrate 11 by an MOCVD (Metal Organic Chemical Vapor Deposition) method. Hence, the semiconductor laminated structure 2 is obtained. Additionally, a gate layer material film 31 that is a material film for the semiconductor gate layer 15 is formed on the second nitride semiconductor layer 14 by the MOCVD method.

Next, as shown in FIG. 4B and FIG. 5B, a gate/pulling-out electrode film 32 that is a material film for the gate electrode 4 and for the hole-pulling-out electrode 6 is formed on the gate layer material film 31 by a sputtering method. In this preferred embodiment, the gate layer material film 31 is a p type GaN film, and the gate/pulling-out electrode film 32 is a TiN film.

Next, as shown in FIG. 4C and FIG. 5C, a resist pattern 33 is formed on the gate/pulling-out electrode film 32 by photolithography so as to cover portions, which respectively serve as the gate electrode 4 and as the pulling-out electrode 6, of the gate/pulling-out electrode film 32 and so as to cover a portion, at which the annular space portion 7a is formed, of the gate/pulling-out electrode film 32. Thereafter, the gate/pulling-out electrode film 32 and the gate layer material film 31 are subjected to patterning by etching while using the resist pattern 33 as a mask.

Hence, the semiconductor gate layer 15 (15A, 15B, 15C) constituted of the gate layer material film 31 and the gate/pulling-out electrode film 32 formed on the semiconductor gate layer 15 are obtained. The semiconductor gate layer 15 is constituted of the ridge portion 15A and the two ridge coupling portions 15B and 15C that couple corresponding end portions of the ridge portion 15A together. The gate/pulling-out electrode film 32 formed on the semiconductor gate layer 15 is constituted of the gate principal electrode portion 4A formed on the ridge portion 15A, the first base portion 4B formed on the first ridge coupling portion 15B, and a portion 32C formed on the second ridge coupling portion 15C. Hence, the gate portion 20 constituted of the ridge portion 15A and the gate principal electrode portion 4A formed thereon is obtained. The resist pattern 33 is removed hereafter. The gate principal electrode portion 4A and the end portion of the ridge portion 15A are not required to coincide with each other, and the end portion of the gate principal electrode portion 4A may be disposed at a more inward position than the end portion of the ridge portion 15A.

Next, as shown in FIG. 4D and FIG. 5D, the passivation film 16 is formed on the front surface of the second nitride semiconductor layer 14 by photolithography and etching so as to cover the entirety of the exposed front surface. The passivation film 16 is constituted of, for example, SiN. Thereafter, the source contact hole 8 and the drain contact hole 9 that reach the second nitride semiconductor layer 14 are formed in the passivation film 16.

Next, a source/drain electrode film is formed so as to cover the entirety of the exposed front surface. Thereafter, the source/drain electrode film is subjected to patterning by photolithography and etching, and, as a result, the source electrode 3 and the drain electrode 5 each of which makes an ohmic contact with the second nitride semiconductor layer 14 are formed as shown in FIG. 4E and FIG. 5E.

Next, as shown in FIG. 5F, the annular opening portion (first annular opening portion) 16a that penetrates through the passivation film 16 in the thickness direction is formed in the passivation film 16 disposed on the second ridge coupling portion 15C. Thereafter, the annular space portion (second annular opening portion) 7a that communicates with the annular opening portion 16a and that penetrates through the gate/pulling-out electrode film 32 in the thickness direction is formed in the gate/pulling-out electrode film 32 formed on the second ridge coupling portion 15C.

Hence, on the second ridge coupling portion 15C, the hole-pulling-out electrode 6 is formed by means of a region surrounded by the annular space portion 7a in the gate/pulling-out electrode film 32, and the second base portion 4C of the gate electrode 4 is formed by a region outside the annular space portion 7a in the gate/pulling-out electrode film 32. The nitride semiconductor device 1 having a structure formed as shown in FIG. 1 to FIG. 3 is obtained in this way.

A description will be given of a comparative example relating to a nitride semiconductor device in which the hole-pulling-out electrode 6 is not formed, i.e., in which the removed region 7 does not exist in the gate electrode 4, in comparison with the nitride semiconductor device 1 of FIG. 1.

An experiment on the comparative example was performed for measuring a gate leak current (hereinafter, referred to as “I_{G}−V_{GS} measurement experiment”). Specifically, a gate-source current I_{G} (gate leak current) was measured while repeatedly and gradually increasing a gate-source voltage V_{GS} [V] from 0 V so that an increment from 0 V becomes larger 1 V by 1 V such as “from 0 V to 5 V,” “from 0 V to 6 V,” . . . , and “from 0 V to 20 V.”

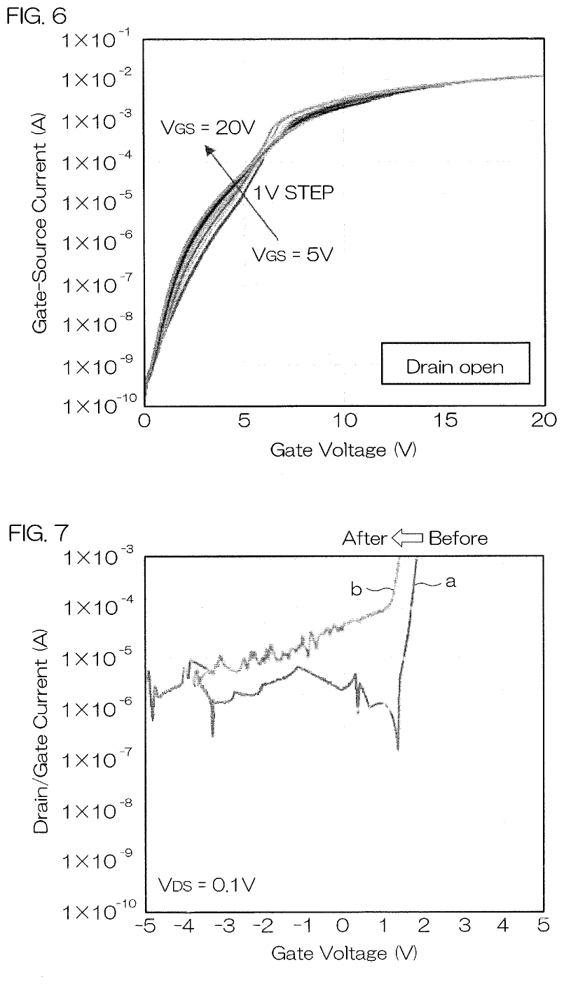

FIG. 6 is a graph showing a result of the I_{G}−V_{GS} measurement experiment on the comparative example.

It is understood from FIG. 6 that fluctuation of a gate leak current characteristic occurs when the increment from 0 V is changed.

The characteristic of a drain current I_{D} with respect to a gate-source V_{GS} was measured relative to the comparative example in which the I_{G}−V_{GS} measurement experiment has not yet been performed. Thereafter, the characteristic of a drain current I_{D} with respect to a gate-source V_{GS} was measured relative to the comparative example in which the I_{G}−V_{GS} measurement experiment has been performed.

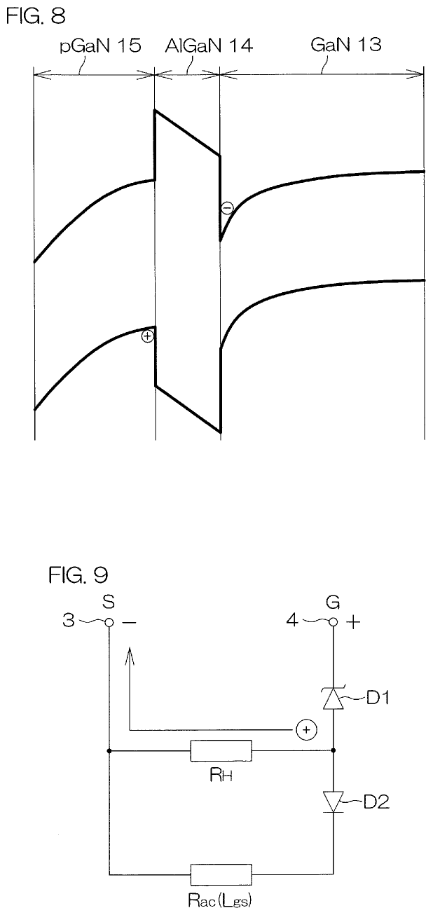

FIG. 7 is a graph showing a measurement result of the drain current I_{D} with respect to the gate-source V_{GS} performed on the comparative example. In FIG. 7, graph “a” shows a measurement result before performing the I_{G}−V_{GS} measurement experiment, and graph “b” shows a measurement result after performing the I_{G}−V_{GS} measurement experiment.

If the gate-source V_{GS} when a drain current I_{D} of 1×10⁻³ Ampere flows is defined as a threshold voltage, the threshold voltage after performing the I_{G}−V_{GS} measurement experiment is lower than the threshold voltage before performing the I_{G}−V_{GS} measurement experiment as shown by an arrow in FIG. 7.

A reason for this will be described. A groove of a conduction band whose resistance is low against electrons is formed near the interface with the second nitride semiconductor layer 14 (AlGaN) in the first nitride semiconductor layer 13 (GaN) as shown in FIG. 8. Hence, a two-dimensional electron gas 10 is formed in the first nitride semiconductor layer 13 (GaN).

On the other hand, a groove of a valence band whose resistance is low against holes is formed near the interface with the second nitride semiconductor layer 14 (AlGaN) in the semiconductor gate layer 15 (pGaN). Therefore, if holes are injected into the semiconductor gate layer 15 (pGaN), it will become impossible for the holes to easily slip out. Hence, a state is reached in which a voltage has been applied to the gate electrode 4 by means of the holes even when a voltage is not applied to the gate electrode 4, and therefore it is conceivable that the threshold voltage has fallen. This tendency becomes more noticeable when the gate electrode 4 makes a Schottky junction with the semiconductor gate layer 15.

FIG. 9 is a circuit diagram showing an equivalent circuit corresponding to the gate-source structure of the nitride semiconductor device 1 of FIG. 1.

The gate electrode 4 is connected to the source electrode 3 through a Schottky diode D1, a pn junction diode D2, a resistor R_{ac} of a two-dimensional electron gas region, and an inductance L_{gs} between the gate and the source. The Schottky diode D1 is a Schottky diode formed by a joint portion between the gate electrode 4 and the semiconductor gate layer 15. The pn junction diode D2 is a diode formed by a joint portion between the semiconductor gate layer 15 and the second nitride semiconductor layer 14.

In this preferred embodiment, the hole-pulling-out electrode 6 is formed at the semiconductor gate layer 15, and the hole-pulling-out electrode 6 is electrically connected to the source electrode 3 by means of an internal wiring. Therefore, a connection point between the Schottky diode D1 and the pn junction diode D2 is connected to the source electrode 3 through a hole recovering path constituted of the hole-pulling-out electrode 6 and an internal wiring by which the hole-pulling-out electrode 6 is connected to the source electrode 3.

In other words, the connection point between the Schottky diode D1 and the pn junction diode D2 is connected to the source electrode 3 through a resistor R_{H} of the hole recovering path. Hence, holes accumulated in the semiconductor gate layer 15 are recovered to the source electrode 3 side through the recovering path as shown by an arrow in FIG. 9. This makes it possible to restrain a fluctuation of the threshold voltage.

Additionally, in this preferred embodiment, it is possible to pull out holes existing in the semiconductor gate layer 15 toward the source electrode side without growing a crystal on the electron supply layer 14 after forming the semiconductor gate layer 15.

Additionally, in this preferred embodiment, the hole-pulling-out electrode 6 is formed in the nonactive area 52, and therefore it is possible to restrain a decrease in the total gate width caused by the presence of the hole-pulling-out electrode 6, and it is possible to restrain an increase in channel resistance.

The length of the active region 51 may be appropriately designed in order to raise the degree of a hole pulling-out effect from the gate principal electrode portion 4A by means of the hole-pulling-out electrode 6. It may be designed to be less than, for example, 80 μm.

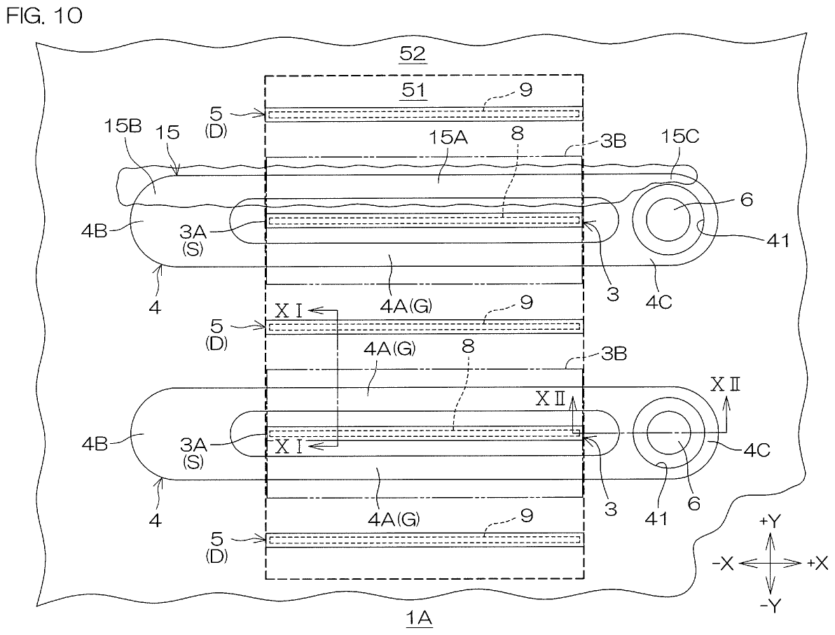

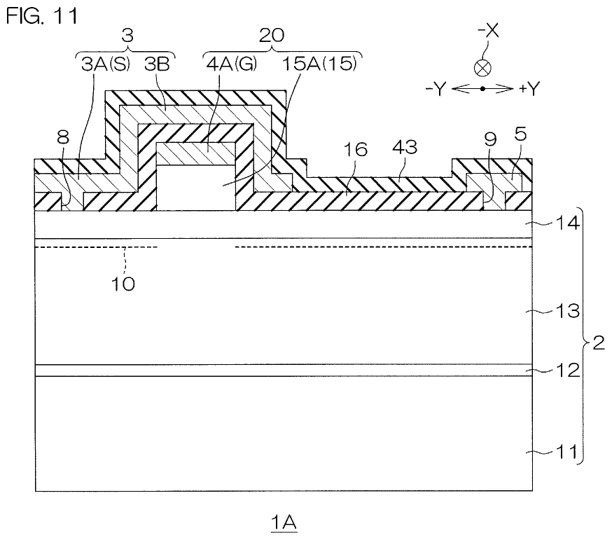

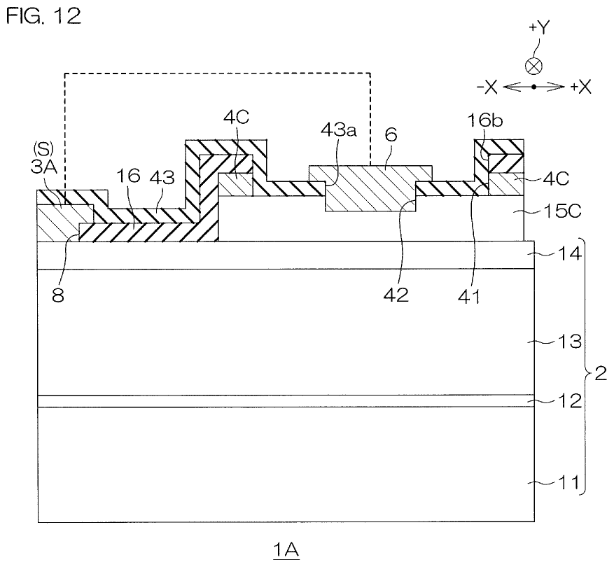

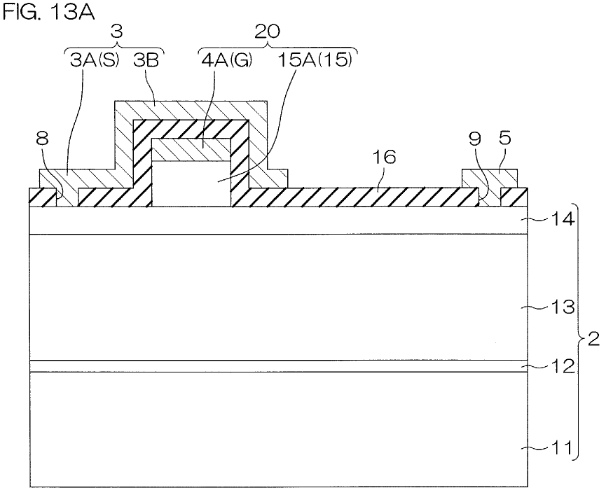

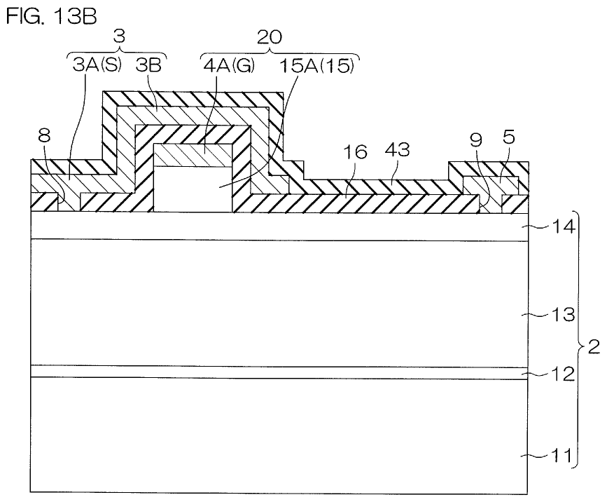

FIG. 10 is a plan view for describing an arrangement of a nitride semiconductor device 1A according to a second preferred embodiment of the present invention. FIG. 11 is a sectional view along line XI-XI of FIG. 10. FIG. 12 is a sectional view along line XII-XII of FIG. 10.

In FIG. 10, the same reference sign as in FIG. 1 is given to a component corresponding to each component of FIG. 1 mentioned above. In FIG. 11, the same reference sign as in FIG. 2 is given to a component corresponding to each component of FIG. 2 mentioned above. In FIG. 12, the same reference sign as in FIG. 3 is given to a component corresponding to each component of FIG. 3 mentioned above.

For descriptive convenience, the passivation film represented by reference sign 16 and an interlayer insulating film represented by reference sign 43 in FIG. 11 and FIG. 12 are omitted in FIG. 10. Additionally, for descriptive convenience, the source principal electrode portion 3A represented by reference sign 3A in FIG. 11 is shown by a solid line in FIG. 10, and the extension portion 3B represented by reference sign 3B in FIG. 11 is omitted in FIG. 10. It should be noted that the outline of the extension portion 3B is shown by an alternate long and two short dashed line in FIG. 10.

The nitride semiconductor device 1A according to the second preferred embodiment differs from the nitride semiconductor device 1 according to the first preferred embodiment chiefly in the structure and the forming method of the hole-pulling-out electrode.

The second base portion 4C of the gate electrode 4 is formed on the second ridge coupling portion 15C of the semiconductor gate layer 15. A removed region (second opening portion) 41 having a circular shape in a plan view is formed at the second base portion 4C of the gate electrode 4. A concave portion 42 having a circular shape in a plan view is formed at a central portion of a front surface exposed to the removed region 41 of a second ridge coupling portion 15C of the semiconductor gate layer 15.

The passivation film (first dielectric film) 16 that covers exposed surfaces of the gate electrode 4 and of the semiconductor gate layer 15 (excluding a region facing the removed region 41) and an exposed surface of the second nitride semiconductor layer 14 (excluding regions facing the source and drain contact holes 8 and 9) is formed on the second nitride semiconductor layer 14. A circular opening (first opening portion) 16b (see FIG. 12) that matches the removed region 41 is formed in the passivation film 16 in a plan view.

An interlayer insulating film (second dielectric film) 43 that covers the side surface and the bottom surface of the removed region 41 (excluding a region facing the concave portion 42), an exposed surface of the passivation film 16, the source electrode 3, and the drain electrode 5 is formed on the second nitride semiconductor layer 14. The interlayer insulating film 43 is constituted of, for example, an SiN film. In the removed region 41, an opening portion (third opening portion) 43a having a circular shape in a plan view that penetrates through the interlayer insulating film 43 in the thickness direction and that communicates with the concave portion 42 is formed in the interlayer insulating film 43. In the removed region 41, the hole-pulling-out electrode 6 having a circular shape in a plan view that covers the opening portion 43a is formed on the interlayer insulating film 43. A portion of the hole-pulling-out electrode 6 enters the opening portion 43a and the concave portion 42, and is joined to the semiconductor gate layer 15 (15C) in the concave portion 42.

The hole-pulling-out electrode 6 and the gate electrode 4 may be constituted of the same material, or may be constituted of mutually different materials. For example, the gate electrode 4 may be constituted of Ti_{z1}N_{1-z1} (0<z1<1), and the hole-pulling-out electrode 6 may be constituted of Ti_{z}2N_{1-z2} (0<z2<1, z1>z2). In this case, the gate electrode 4 makes a first Schottky contact with the semiconductor gate layer 15, and the hole-pulling-out electrode 6 makes a second Schottky contact with the semiconductor gate layer 15. The first Schottky contact becomes higher in barrier height against holes than the second Schottky contact.

Additionally, for example, the gate electrode 4 may be constituted of TiN, and the hole-pulling-out electrode 6 may be constituted of Ti/Al. In this case, the gate electrode 4 makes a Schottky contact with the semiconductor gate layer 15, and the hole-pulling-out electrode 6 makes an ohmic contact with the semiconductor gate layer 15.

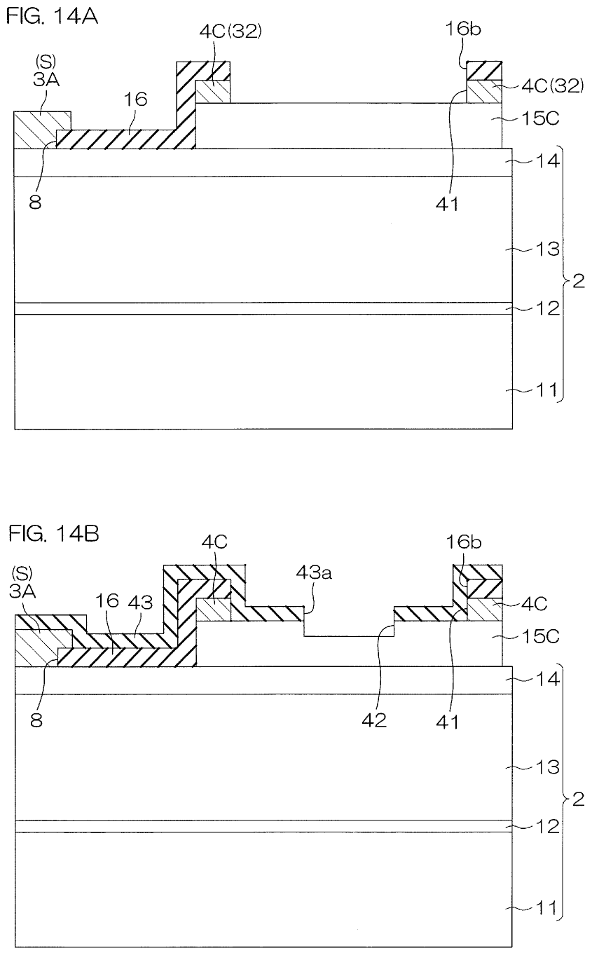

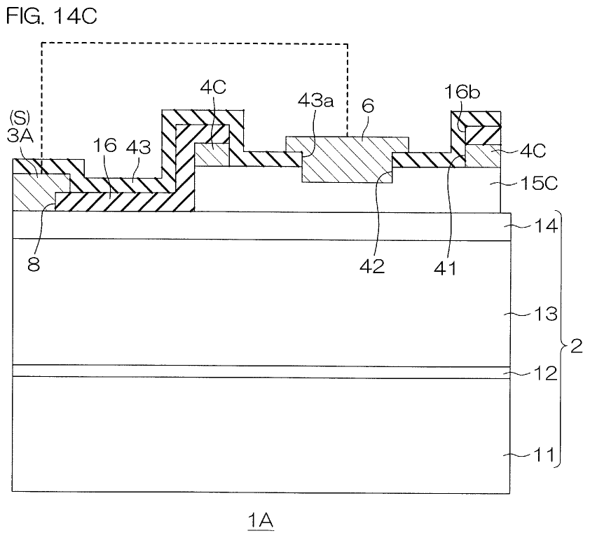

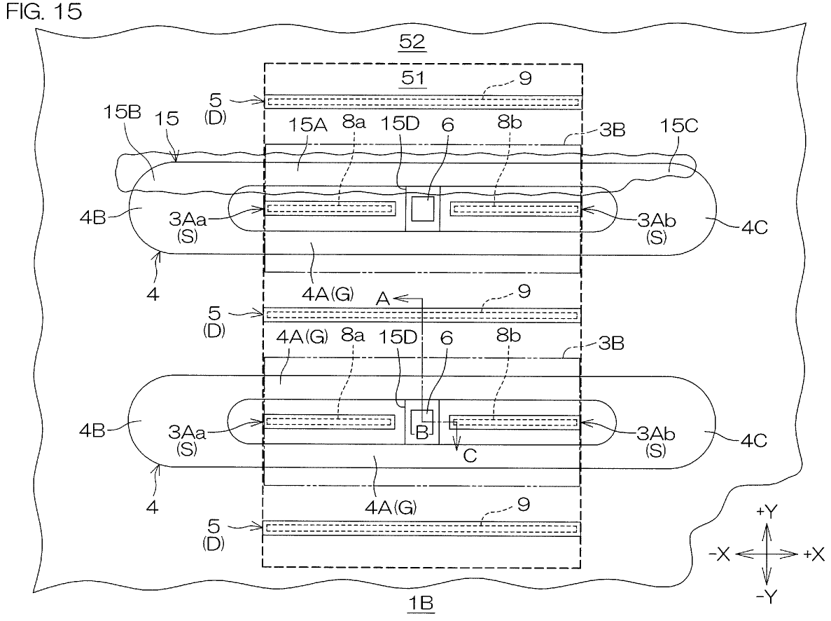

FIG. 13A and FIG. 13B and FIG. 14A to FIG. 14C are sectional views for describing an example of a manufacturing process of the nitride semiconductor device 1A and in which cross-sectional structures in a plurality of steps of the manufacturing process are shown. FIG. 13A and FIG. 13B are sectional views corresponding to the section plane of FIG. 11, and FIG. 14A to FIG. 14C are sectional views corresponding to the section plane of FIG. 12.

The manufacturing process of FIG. 4A to FIG. 4E and FIG. 5A to FIG. 5E of the nitride semiconductor device 1 according to the first preferred embodiment is also common to that of the nitride semiconductor device 1A according to the second preferred embodiment. However, in the second preferred embodiment, “the gate/pulling-out electrode film 32 that is a material for the gate electrode 4 and the hole-pulling-out electrode 6” mentioned in the first preferred embodiment is mentioned as “the gate electrode film 32 that is a material film for the gate electrode 4.”

When the source electrode 3 and the drain electrode 5 are formed by the steps of FIG. 4E and FIG. 5E mentioned above, a circular opening portion (first opening portion) 16b that penetrates through the passivation film 16 in the thickness direction is formed in the passivation film 16 disposed on the second ridge coupling portion 15C by photolithography and etching as shown in FIG. 13A (same as FIG. 4E) and FIG. 14A. Thereafter, the removed region (second opening portion) 41 that communicates with the circular opening portion 16b is formed in the gate electrode film 32 formed on the second ridge coupling portion 15C. Hence, the second base portion 4C of the gate electrode 4 is formed on the second ridge coupling portion 15C.

Next, as shown in FIG. 13B and FIG. 14B, the interlayer insulating film 43 with which an exposed entire surface is covered is formed. Thereafter, the opening portion (third opening portion) 43a circular in a plan view is formed in the interlayer insulating film 43 in the removed region 41 in a plan view by photolithography and etching, and then the concave portion 42 that communicates with the opening portion 43a is formed at the semiconductor gate layer 15.

Next, as shown in FIG. 14C, the hole-pulling-out electrode 6 that covers the opening portion 43a and that is joined to the second ridge coupling portion 15C in the concave portion 42 is formed on the interlayer insulating film 43 in the removed region 41 in a plan view. Hence, the nitride semiconductor device 1A having a structure shown in FIG. 10 to FIG. 12 is obtained.

Even in the nitride semiconductor device 1A according to the second preferred embodiment, the same effect as in the nitride semiconductor device 1 according to the first preferred embodiment is obtained. In the nitride semiconductor device 1A according to the second preferred embodiment, the thickness of a region in which the hole-pulling-out electrode 6 is formed in the semiconductor gate layer 15 is thinner than the thickness of the ridge portion 15A. Hence, in the nitride semiconductor device 1A according to the second preferred embodiment, it is possible to more effectively pull out holes accumulated near the interface with the second nitride semiconductor layer 14 in the semiconductor gate layer 15 toward the source electrode 3 side than in the nitride semiconductor device 1 according to the first preferred embodiment.

In the nitride semiconductor device 1A according to the second preferred embodiment, the concave portion 42 is not required to be formed, although the concave portion 42 is formed at the second ridge coupling portion 15C. In this case, the hole-pulling-out electrode 6 formed on the interlayer insulating film 43 so as to cover the opening portion 43a is joined to the front surface of the second ridge coupling portion 15C.

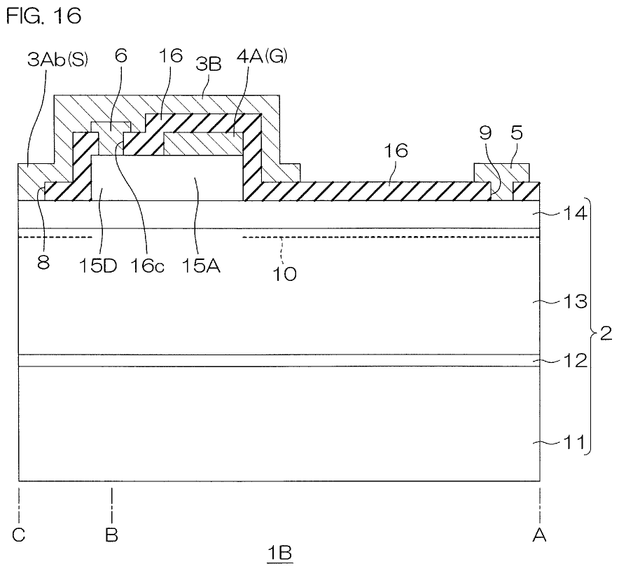

FIG. 15 is a plan view for describing a nitride semiconductor device 1B according to a third preferred embodiment of the present invention. FIG. 16 is a sectional view along line A-B-C of FIG. 15.

In FIG. 15, the same reference sign as in FIG. 1 is given to a component corresponding to each component of FIG. 1 mentioned above. In FIG. 16, the same reference sign as in FIG. 2 and FIG. 3 is given to a component corresponding to each component of FIG. 2 and FIG. 3 mentioned above.

For descriptive convenience, the passivation film represented by reference sign 16 in FIG. 16 is omitted in FIG. 15. Additionally, for descriptive convenience, in FIG. 15, first and second source principal electrode portions 3Aa and 3Ab are each shown by a solid line, and the extension portion 3B represented by reference sign 3B in FIG. 16 is omitted. It should be noted that the outline of the extension portion 3B is shown by an alternate long and two short dashed line in FIG. 15.

Also in the nitride semiconductor device 1B according to the third preferred embodiment, the source electrode 3 is constituted of the source principal electrode portion 3A and the extension portion 3B. However, the source principal electrode portion 3A has its length direction intermediate portion cut off, and is separated into the first source principal electrode portion 3Aa and the second source principal electrode portion 3Ab. Similarly, the source contact hole 8 has its length direction intermediate portion cut off, and is constituted of a first hole portion 8a through which the first source principal electrode portion 3Aa penetrates and a second hole portion 8b through which the second source principal electrode portion 3Ab penetrates.

In this preferred embodiment, the first and second source principal electrode portions 3Aa and 3Ab shall refer to a region surrounded by the outline of the first and second hole portions 8a and 8b corresponding thereto and its peripheral region of the entire region of the source electrode 3 in a plan view. The extension portion 3B refers to a portion of the entire region of the source electrode 3 other than the first and second source principal electrode portions 3Aa and 3Ab in a plan view. The extension portion 3B covers substantially the entire region of the pair of gate principal electrode portions 4A. The first and second source principal electrode portions 3Aa and 3Ab are one example of the “source principal electrode” of the present invention.

The semiconductor gate layer 15 includes the pair of ridge portions 15A, the first and second ridge coupling portions 15B and 15C that respectively couple corresponding end portions of the pair of ridge portions 15A together, and a third coupling portion 15D that couples length central portions of the pair of ridge portions 15A together. The third coupling portion 15D is disposed between the first source principal electrode portion 3Aa and the second source principal electrode portion 3Ab. In other words, the third coupling portion 15D is disposed in a region deviating from a region in which the first and second source principal electrode portions 3Aa and 3Ab face the drain electrode 5. The third coupling portion 15D is an example of the “extension portion” of the present invention.

The gate electrode 4 is constituted of the gate principal electrode portion 4A formed on the pair of ridge portions 15A and the second and third base portions 4B and 4C formed on the first and second ridge coupling portions 15B and 15C, respectively.

The passivation film 16 that covers exposed surfaces of the gate electrode 4 and of the semiconductor gate layer 15 and an exposed surface of the second nitride semiconductor layer 14 (excluding regions facing the source contact hole 8 (8a, 8b) and the drain contact hole 9) is formed on the second nitride semiconductor layer 14. An opening portion 16c having a rectangular shape in a plan view is formed in a central portion of the passivation film 16 on the third coupling portion 15D. The hole-pulling-out electrode 6 with which the opening portion 16c is covered is formed on the passivation film 16 on the third coupling portion 15D. A portion of the hole-pulling-out electrode 6 enters the opening portion 16c, and is joined to the semiconductor gate layer 15 (15D) in the opening portion 16c.

Even in the nitride semiconductor device 1B according to the third preferred embodiment, the same effect as in the nitride semiconductor device 1 according to the first preferred embodiment is obtained.

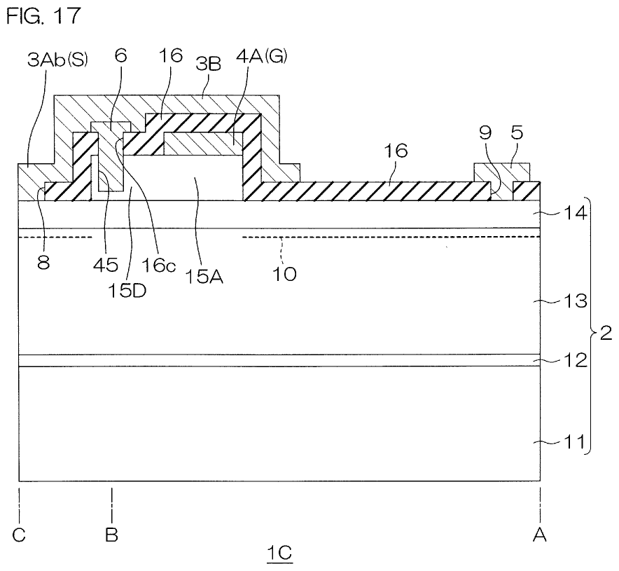

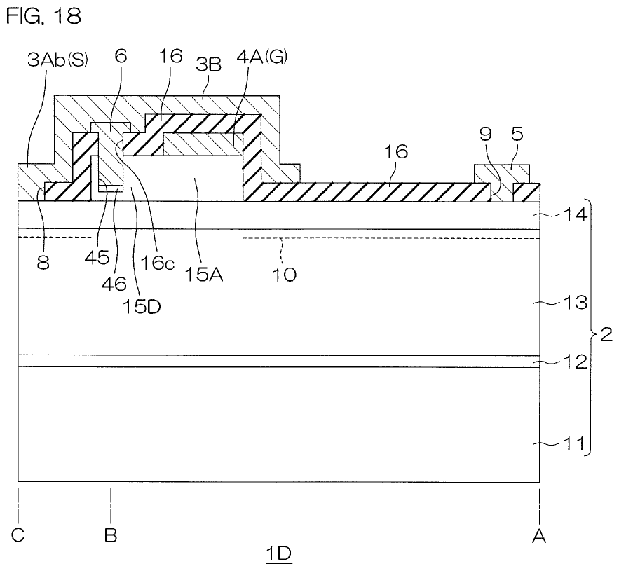

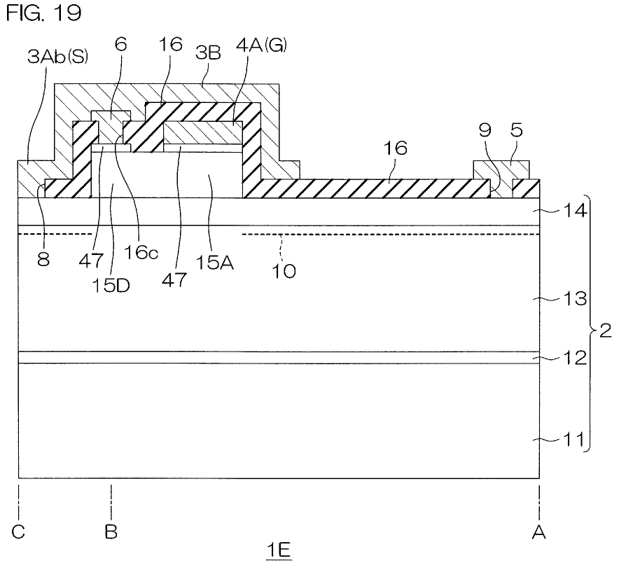

FIG. 17, FIG. 18, and FIG. 19 are sectional views showing first, second, and third modification examples, respectively, of the nitride semiconductor device 1B according to the third preferred embodiment, and are sectional views corresponding to the sectional view of FIG. 16. In FIG. 17, FIG. 18, and FIG. 19, the same reference sign as in FIG. 16 is given to a component corresponding to each component of FIG. 16 mentioned above.

Referring to FIG. 17, in a nitride semiconductor device 10 according to the first modification example, a concave portion 45 that communicates with the opening portion 16c is formed at a front surface of the third coupling portion 15D of the semiconductor gate layer 15. The hole-pulling-out electrode 6 with which the opening portion 16c and the concave portion 45 are covered is formed on the passivation film 16 on the third coupling portion 15D. A portion of the hole-pulling-out electrode 6 enters the opening portion 16c and the concave portion 45, and is joined to the semiconductor gate layer 15 (15D) in the concave portion 45.

In the first modification example, the thickness of a region in which the hole-pulling-out electrode 6 is formed in the semiconductor gate layer 15 is thinner than the thickness of the ridge portion 15A. Hence, in the first modification example, it is possible to more effectively pull out holes accumulated near the interface with the second nitride semiconductor layer 14 in the semiconductor gate layer 15 to the source electrode 3 side than the nitride semiconductor device 1B according to the third preferred embodiment.

Referring to FIG. 18, a nitride semiconductor device 1D according to the second modification example is substantially the same as the nitride semiconductor device 10 according to the first modification example. Also in the second modification example, the concave portion 45 communicating with the opening portion 16c is formed at the front surface of the third coupling portion 15D of the semiconductor gate layer 15 in the same way as in the first modification example. In the second modification example, an n type region (n type GaN) 46 is formed in a surface layer portion of a bottom surface of the concave portion 45. The hole-pulling-out electrode 6 with which the opening portion 16c and the concave portion 45 are covered is formed on the passivation film 16 on the third coupling portion 15D. A portion of the hole-pulling-out electrode 6 enters the opening portion 16c and the concave portion 45, and is joined to the n type region 46 of the semiconductor gate layer 15 in the concave portion 45.

Referring to FIG. 19, a nitride semiconductor device 1E according to the third modification example is substantially the same as the nitride semiconductor device 1B according to the third preferred embodiment. The third modification example differs from the first modification example in the point that a third nitride semiconductor layer 47 is interposed between the semiconductor gate layer 15 and the gate electrode 4 and between the semiconductor gate layer 15 and the hole-pulling-out electrode 6. The third nitride semiconductor layer 47 is, for example, an n type GaN layer. The third nitride semiconductor layer 47 may be an AlGaN layer.

Although the preferred embodiments of the present invention have been described above, the present invention may be implemented in yet other preferred embodiments. For example, in the first and second preferred embodiments, the hole-pulling-out electrode 6 is formed only on the second ridge coupling portion 15C of the first and second ridge coupling portions 15B and 15C, and yet the hole-pulling-out electrode 6 may be formed only on the first ridge coupling portion 15B. Additionally, the hole-pulling-out electrode 6 may be formed at each of the first and second ridge coupling portions 15B and 15C.

Additionally, although with each of the preferred embodiments described above, silicon was taken up as an example of the material of the substrate 11, any substrate material besides this, such as a sapphire substrate, a GaN substrate, etc., may be applied.

While preferred embodiments of the present invention were described in detail above, these are merely specific examples used to clarify the technical contents of the present invention and the present invention should not be interpreted as being limited to these specific examples and the scope of the present invention is limited only by the appended claims.

The present application corresponds to Japanese Patent Application No. 2019-090147 filed on May 10, 2019 in the Japan Patent Office, and the entire disclosure of this application is incorporated herein by reference.

### REFERENCE SIGNS LIST

1, 1A, 1B, 1C, 1E nitride semiconductor device
2 semiconductor laminated structure
3 source electrode
3A source principal electrode portion
3Aa first source principal electrode portion
3Ab second source principal electrode portion
3B extension portion
4 gate electrode
4A gate principal electrode portion
4B, 4C base portion
5 drain electrode
6 hole-pulling-out electrode
7 removed region
7a annular space portion (second annular opening portion)
8 source contact hole
8a first hole portion
8b second hole portion
9 drain contact hole
10 two-dimensional electron gas (2DEG)
11 substrate
12 buffer layer
13 first nitride semiconductor layer (electron transit layer)
14 second nitride semiconductor layer (electron supply layer)
15 semiconductor gate layer
15A ridge portion
15B, 15C, 15D ridge coupling portion
16 passivation film
16a annular opening portion (first annular opening portion)
16b circular opening portion (first opening portion)
20 gate portion
31 gate layer material film
32 gate/pulling-out electrode film
33 resist pattern
34 source/drain electrode film
41 removed region (second opening portion)
42 concave portion
43 interlayer insulating film
43a opening portion (third opening portion)
44 opening portion
45 concave portion
46 n type region
47 third nitride semiconductor layer
51 active area
52 nonactive area

1. A nitride semiconductor device comprising:
a first nitride semiconductor layer that constitutes an electron transit layer;
a second nitride semiconductor layer that is formed on the first nitride semiconductor layer and that constitutes an electron supply layer;
a semiconductor gate layer that is disposed on the second nitride semiconductor layer and that has a ridge portion at at-least a portion of the semiconductor gate layer and that includes an acceptor type impurity;
a gate electrode that is formed at least on the ridge portion of the semiconductor gate layer;
a source electrode and a drain electrode that are disposed on the second nitride semiconductor layer; and
a hole-pulling-out electrode that is formed on the semiconductor gate layer in order to pull out holes existing in the semiconductor gate layer and that is electrically connected to the source electrode.

2. The nitride semiconductor device according to claim 1, wherein the source electrode has a source principal electrode portion parallel to the ridge portion,
the drain electrode is disposed so as to face the source principal electrode portion across the ridge portion,
the semiconductor gate layer has an extension portion formed in a region in which the source principal electrode portion and the drain electrode do not face each other, and
the hole-pulling-out electrode is formed in a region in which the gate electrode is not formed in a front surface of the extension portion.

3. The nitride semiconductor device according to claim 2, wherein the semiconductor gate layer is disposed so as to surround the source principal electrode portion in a plan view,
the semiconductor gate layer has a pair of the ridge portions respectively disposed at both sides of the source principal electrode portion and two ridge coupling portions that couple corresponding end portions of these ridge portions together,
the drain electrode faces the source principal electrode portion across one of the pair of the ridge portions, and
the hole-pulling-out electrode is formed on at least one of the two ridge coupling portions.

4. The nitride semiconductor device according to claim 3, wherein the gate electrode has a pair of gate principal electrode portions formed on the pair of the ridge portions, respectively, and two base portions that are formed on the ridge coupling portion and that couple corresponding end portions of the pair of the gate principal electrode portions together,
a removed region in which the base portion is not formed is formed at at-least one of the two base portions, and
the hole-pulling-out electrode is formed on a front surface of the ridge coupling portion in the removed region.

5. The nitride semiconductor device according to claim 4, wherein the gate principal electrode portion and the drain electrode are disposed at both sides of the source principal electrode portion in order of short-to-long distance from the source principal electrode portion.

6. The nitride semiconductor device according to claim 1, wherein a thickness of a region in which the hole-pulling-out electrode is formed in the semiconductor gate layer is thinner than a thickness of the ridge portion.

7. The nitride semiconductor device according to claim 4, wherein the ridge coupling portion directly under the removed region has a thin film region whose thickness is thinner than a thickness of the ridge portion, and the hole-pulling-out electrode is formed on a front surface of the thin film region.

8. The nitride semiconductor device according to claim 1, wherein the hole-pulling-out electrode and the gate electrode are constituted of mutually different materials.

9. The nitride semiconductor device according to claim 8, wherein the gate electrode makes a first Schottky contact with the semiconductor gate layer,
the hole-pulling-out electrode makes a second Schottky contact with the semiconductor gate layer, and
the first Schottky contact is higher in barrier height against holes than the second Schottky contact.

10. The nitride semiconductor device according to claim 8, wherein the gate electrode makes a Schottky contact with the semiconductor gate layer, and
the hole-pulling-out electrode makes an ohmic contact with the semiconductor gate layer.

11. The nitride semiconductor device according to claim 1, wherein a third nitride semiconductor layer is formed between the hole-pulling-out electrode and the semiconductor gate layer.

12. The nitride semiconductor device according to claim 1, wherein the first nitride semiconductor layer is constituted of a GaN layer,
the second nitride semiconductor layer is constituted of an AlₓGa₍₁₋ₓ₎N (0<x<1) layer, and
the semiconductor gate layer is constituted of a p type GaN layer.

13. A method for manufacturing a nitride semiconductor device comprising:
a step of forming a first nitride semiconductor layer that constitutes an electron transit layer, a second nitride semiconductor layer that constitutes an electron supply layer, and a semiconductor gate layer material film that includes an acceptor type impurity in this order on a substrate;
a step of forming an electrode film that is a material film for a gate electrode and a hole-pulling-out electrode on the semiconductor gate layer material film;
a step of forming a semiconductor gate layer having a ridge portion that has a ridge shape and an extension portion that extends from the ridge portion and an electrode film formed on the semiconductor gate layer by means of patterning achieved by etching the electrode film and the semiconductor gate layer material film;
a step of forming a first dielectric film so as to cover exposed surfaces of the electrode film, of the semiconductor gate layer, and of the second nitride semiconductor layer, and hereafter forming a source contact hole and a drain contact hole that penetrate through the first dielectric film in a thickness direction at mutually-facing positions between which the ridge portion is interposed in the first dielectric film;
a step of forming a source electrode and a drain electrode that penetrate through the source contact hole and the drain contact hole and that come into contact with the second nitride semiconductor layer; and
a step of, in the extension portion, forming a first annular opening portion having an annular shape in a plan view in the first dielectric film and forming a second annular opening portion having an annular shape in a plan view that communicates with the first annular opening portion in the electrode film, and hence forming the hole-pulling-out electrode that is constituted of the electrode film disposed inside the second annular opening portion and that comes into contact with the extension portion and the gate electrode that is constituted of the electrode film disposed outside the second annular opening portion.

14. A method for manufacturing a nitride semiconductor device comprising:
a step of forming a first nitride semiconductor layer that constitutes an electron transit layer, a second nitride semiconductor layer that constitutes an electron supply layer, and a semiconductor gate layer material film that includes an acceptor type impurity in this order on a substrate;
a step of forming a gate electrode film that is a material film for a gate electrode on the semiconductor gate layer material film;
a step of forming a semiconductor gate layer having a ridge portion that has a ridge shape and an extension portion that extends from the ridge portion and a gate electrode film formed on the semiconductor gate layer by means of patterning achieved by etching the gate electrode film and the semiconductor gate layer material film;
a step of forming a first dielectric film so as to cover exposed surfaces of the gate electrode film, of the semiconductor gate layer, and of the second nitride semiconductor layer, and hereafter forming a source contact hole and a drain contact hole that penetrate through the first dielectric film in a thickness direction at mutually-facing positions between which the ridge portion is interposed in the first dielectric film;
a step of forming a source electrode and a drain electrode that penetrate through the source contact hole and the drain contact hole and that come into contact with the second nitride semiconductor layer;
a step of, in the extension portion, forming a first opening portion that penetrates through the first dielectric film in a thickness direction and forming a second opening portion that communicates with the first opening portion in the gate electrode film, and hence forming a gate electrode;
a step of forming a second dielectric film with which a bottom surface of the second opening portion is covered;
a step of forming a third opening portion that penetrates through the second dielectric film in the thickness direction in the second dielectric film; and
a hole-pulling-out electrode forming step of forming a hole-pulling-out electrode that covers the third opening portion and that comes into contact with the extension portion.

15. The method for manufacturing a nitride semiconductor device according to claim 14, wherein the hole-pulling-out electrode forming step includes:
a step of forming a concave portion that communicates with the third opening portion at a front surface of the extension portion and
a step of forming a hole-pulling-out electrode that is formed on the second dielectric film so as to cover the third opening portion and that has a portion in contact with the extension portion in the concave portion.
